(19) United States
(12) Patent Application Publication
(10) Pub. No.: US 2024/0243093 A1
(43) Pub. Date: Jul. 18, 2024

(54) SEMICONDUCTOR MODULE AND WIRING MEMBER

(71) Applicant: FUJI ELECTRIC CO., LTD., Kawasaki-shi (JP)

(72) Inventors: Koji OSAKI, Matsumoto-city (JP); Yuichiro HINATA, Matsumoto-city (JP)

(73) Assignee: FUJI ELECTRIC CO., LTD., Kawasaki-shi (JP)

(21) Appl. No.: 18/519,652

(22) Filed: Nov. 27, 2023

(30) Foreign Application Priority Data
Jan. 16, 2023 (JP) 2023-004469

(51) Int. Cl. H01L 23/00

(52) U.S. Cl. CPC H01L 24/40; H01L 24/32; H01L 24/73; H01L 2224/32227; H01L 2224/32238; H01L 2224/4007; H01L 2224/40229; H01L 2224/73263; H01L 2924/13055

(57) ABSTRACT

A semiconductor module includes a semiconductor chip arranged on a mounting board, and a wiring member electrically connected to the semiconductor chip. The wiring member includes a body portion elongated in the direction of a Y-axis, and one or more ridges protruding from a surface of a flat plate-shaped portion of the body portion and extending along the Y-axis.

### CROSS REFERENCE TO RELATED APPLICATIONS

This application is based on, and claims priority from, Japanese Patent Application No. 2023-004469, filed Jan. 16, 2023, the entire content of which is incorporated herein by reference.

### BACKGROUND

### Field of the Invention

The present disclosure relates to a semiconductor module and to a wiring member.

### Description of Related Art

In semiconductor modules on which a semiconductor chip such as an Insulated Gate Bipolar Transistor (IGBT) is mounted, a wiring member such as a lead frame electrically connected to the semiconductor chip is used, for example. Japanese Patent Application Laid-Open Publication No. 2021-197440 discloses a configuration in which a recessed portion is formed in a region functioning as an external connection terminal in a lead frame and side edges are formed on side surfaces of a portion at which the recessed portion is formed.

A thin plate-shaped wiring member including an end portion joined to a semiconductor chip, and a flat plate-shaped portion (hereinafter, “extending portion”) linearly extending in a predetermined direction is proposed. However, there is a problem in that the extending portion is likely to deform, for example, during transportation or assembly of the wiring member, because it is difficult to secure sufficient mechanical strength in the extending portion.

### SUMMARY

In view of the above circumstances, an object of one aspect of the present disclosure is to minimize deformation of the wiring member.

In order to solve the above problem, a semiconductor module according to one aspect of the present disclosure includes: a semiconductor chip arranged on a substrate; and a wiring member electrically connected to the semiconductor chip, in which the wiring member includes: a body portion elongated in a first direction; and one or more ridges protruding from a surface of a flat plate-shaped portion of the body portion and extending along the first direction.

In another aspect, a wiring member according to the present disclosure is a wiring member electrically connected to a semiconductor chip, and includes: a body portion elongated in a first direction; and one or more ridges protruding from a surface of a flat plate-shaped portion of the body portion and extending along the first direction.

### BRIEF DESCRIPTION OF THE DRAWINGS

FIG. 1 is a cross-sectional view of a semiconductor module according to a first embodiment;

FIG. 2 is a perspective view of a wiring member;

FIG. 3 is a side view of the wiring member;

FIG. 4 is a cross-sectional view taken along line IV-IV in FIG. 2;

FIG. 5 is a cross-sectional view taken along line V-V in FIG. 2;

FIG. 6 is a graph showing a relationship between the height and the width of a ridge and the maximum deformation amount of the wiring member;

FIG. 7 is a graph showing a relationship between the height and the width of the ridge and the maximum deformation amount of the wiring member;

FIG. 8 is an explanatory diagram of a manufacturing method of the wiring member;

FIG. 9 is an explanatory diagram of a manufacturing method of a wiring member according to a second embodiment;

FIG. 10 is an explanatory diagram of a manufacturing method of a wiring member according to a third embodiment;

FIG. 11 is a side view of a wiring member according to a modification;

FIG. 12 is a cross-sectional view of the wiring member according to a modification;

FIG. 13 is a cross-sectional view of the wiring member according to a modification;

FIG. 14 is a cross-sectional view of the wiring member according to a modification;

FIG. 15 is a side view of a part of the wiring member according to a modification; and

FIG. 16 is a cross-sectional view of a semiconductor module according to a modification.

### DESCRIPTION OF EMBODIMENTS

Embodiments for implementing the present disclosure are explained with reference to the drawings. It is to be noted that the dimensions and scales of elements in the drawings are different from actual products, as appropriate. The embodiments explained below are specific examples that are assumed when the present disclosure is implemented. Therefore, the scope of the present disclosure is not limited to the following embodiments.

### A: First Embodiment

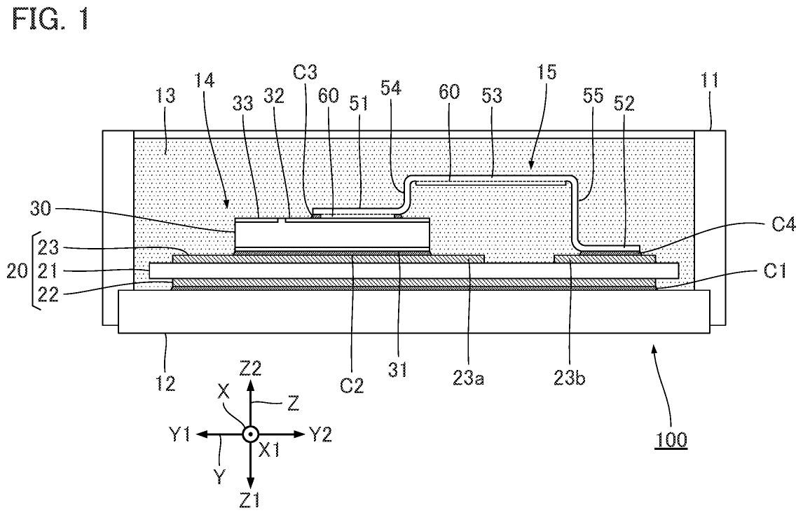

FIG. 1 is a cross-sectional view of a semiconductor module 100 according to a first embodiment. The semiconductor module 100 of the first embodiment is, for example, a power semiconductor device that constitutes a power converter such as an inverter circuit. The semiconductor module 100 includes a housing 11, a heatsink 12, a sealing material 13, a semiconductor unit 14, and a wiring member 15.

In the following explanations, an X-axis, a Y-axis, and a Z-axis orthogonal to each other are assumed. One direction along the X-axis is denoted as an “X1 direction” and the direction opposite to the X1 direction is denoted as an “X2 direction”. Similarly, one direction along the Y-axis is denoted as a “Y1 direction” and the direction opposite to the Y1 direction is denoted as a “Y2 direction”. One direction along the Z-axis is denoted as a “Z1 direction” and the direction opposite to the Z1 direction is denoted as a “Z2 direction”. Viewing a certain element of the semiconductor module 100 along a direction (the Z1 direction or the Z2 direction) of the Z-axis is hereinafter referred to as “plan view”.

While the semiconductor module 100 can be installed in any direction in situations of practical use, the Z1 direction is assumed to be a downward direction and the Z2 direction is assumed to be an upward direction for the sake of convenience in the following explanations. Therefore, in some cases, a surface of a certain element of the semiconductor module 100 facing the Z1 direction is referred to as a “lower surface” and a surface of the element facing the Z2 direction is referred to as an “upper surface”.

The housing 11 is a housing that houses the semiconductor unit 14, the wiring member 15, and the sealing member 13. The housing 11 is made of, for example, various types of insulating resins such as polyphenylene sulfide (PPS) resin, polybutylene terephthalate (PBT) resin, polybutylene succinate (PBS) resin, polyamide (PA) resin, or acrylonitrile-butadiene-styrene (ABS) resin. External terminals (although not shown) for electrically connecting the semiconductor unit 14 to external devices are arranged on the housing 11.

The heatsink 12 is a rectangular plate-shaped member that supports the semiconductor unit 14 and functions as a cooling mechanism that radiates heat generated in the semiconductor unit 14. The heatsink 12 is made of, for example, a conductive material such as aluminum or copper and is fixed to the housing 11. The heatsink 12 maybe used as a grounding body set to a ground potential.

The sealing material 13 is an insulating material filled in a space between the housing 11 and the heatsink 12, and seals the semiconductor unit 14 and the wiring member 15. The sealing material 13 is made of, for example, a resin material such as epoxy resin. The sealing material 13 may contain, for example, various types of fillers such as silicon oxide or aluminum oxide.

The semiconductor unit 14 includes a mounting board 20 and a semiconductor chip 30. The mounting board 20 is a wiring board on which the semiconductor chip 30 is mounted. For example, a substrate such as a Direct Copper Bonding (DCB) substrate, an Active Metal Brazing (AMB) substrate, or an Insulated Metal Substrate (IMS) is used as the mounting board 20. The mounting board 20 is an example of a “substrate”.

Specifically, the mounting board 20 is constituted of stacked layers including an insulating substrate 21, a metal layer 22, and conductive patterns 23. The insulating substrate 21 is a rectangular plate-shaped member made of an insulating material. The insulating substrate 21 is made of, for example, a ceramic material such as aluminum oxide, aluminum nitride, or silicon nitride, or a resin material such as epoxy resin.

The metal layer 22 is a rectangular plate-shaped member joined to the lower surface of the insulating substrate 21. The metal layer 22 is made of, for example, a highly thermally conductive metal material such as copper or aluminum and conducts heat generated in the semiconductor chip 30 to the heatsink 12. The lower surface of the metal layer 22 is joined to the upper surface of the heatsink 12 by a joining material C1 such as solder or a sintered material. The conductive patterns 23 (23a and 23b) are conductors formed on the upper surface of the insulating substrate 21. Each of the conductive patterns 23 is made of, for example, a low-resistance conductive material such as copper or a copper alloy.

The semiconductor chip 30 is a power semiconductor element arranged on the mounting board 20. Specifically, the semiconductor chip 30 is joined to the mounting board 20 by a conductive joining material C2. The joining material C2 is, for example, a conductive material such as solder or a sintered material. The semiconductor chip 30 of the first embodiment is joined to the conductive pattern 23a.

The semiconductor chip 30 is, for example, a switching element such as an Insulated Gate Bipolar Transistor (IGBT). A plurality of the semiconductor chips 30 can practically be arranged on the mounting board 20. However, only one semiconductor chip 30 is illustrated in FIG. 1 for the sake of convenience.

The semiconductor chip 30 includes a first main electrode 31, a second main electrode 32, and a control electrode 33. The first main electrode 31 and the second main electrode 32 are electrodes to which a current to be controlled is input, and from which a current to be controlled is output. The first main electrode 31 is a collector electrode that constitutes the lower surface of the semiconductor chip 30 and is joined to the conductive pattern 23a by the joining material C2. The second main electrode 32 is an emitter electrode that constitutes the upper surface of the semiconductor chip 30. The control electrode 33 is a gate electrode to which a control voltage for controlling turning ON and OFF of the semiconductor chip 30 is applied. The control electrode 33 and the second main electrode 32 together constitute the upper surface of the semiconductor chip 30.

The wiring member 15 is a thin plate-shaped conductor electrically connected to the semiconductor chip 30. The wiring member 15 is made of, for example, a low-resistance conductive material such as copper or a copper alloy. The wiring member 15 of the first embodiment is elongated along the Y-axis and electrically connects the second main electrode 32 of the semiconductor chip 30 to the conductive patterns 23b of the mounting board 20. The wiring member 15 is referred to also as a “lead frame”.

According to a form in which the plate-shaped wiring member 15 is arranged in the manner described above, the semiconductor chip 30 does not need to be connected to the conductive patterns 23b by linear wires. That is, the semiconductor chip 30 can be connected to all conductive patterns 23b with a single wiring member 15. Therefore, there is an advantage in that the configuration of the semiconductor module 100 and the manufacturing process thereof can be simplified.

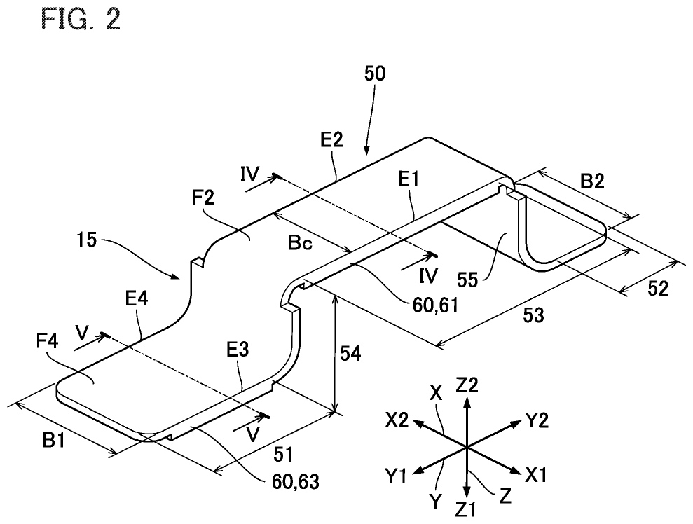

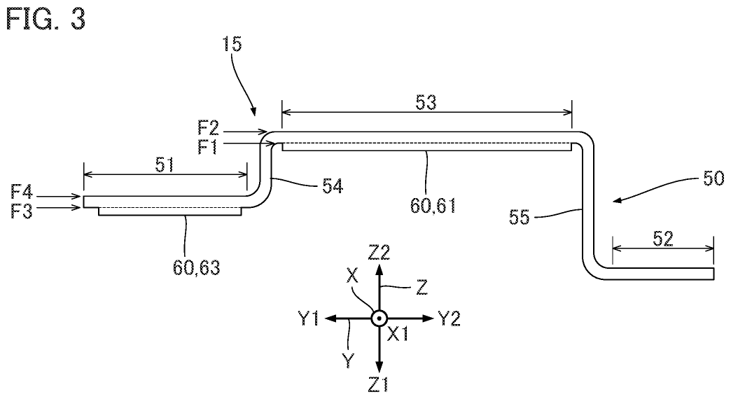

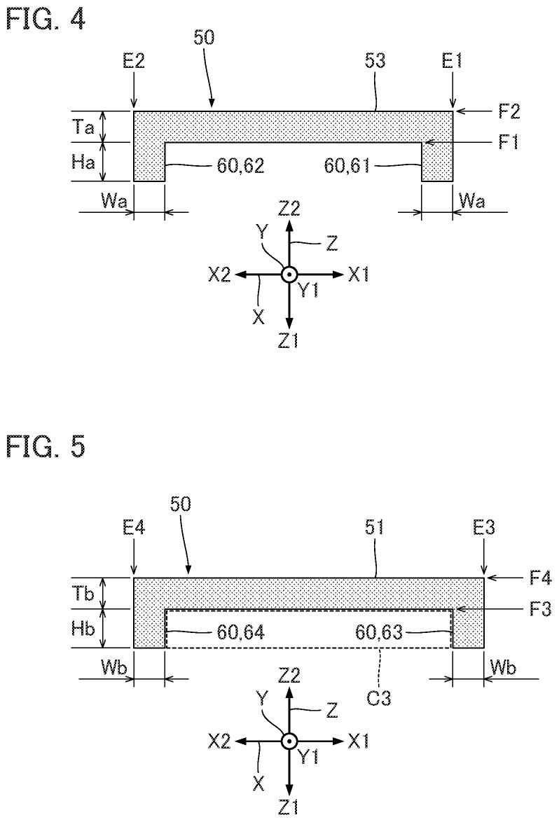

FIG. 2 is a perspective view illustrating the configuration of the wiring member 15 and FIG. 3 is a side view of the wiring member 15. FIG. 4 is a cross-sectional view taken along line IV-IV in FIG. 2, and FIG. 5 is a cross-sectional view taken along line V-V in FIG. 2. In the following explanations, the dimension of each portion in the wiring member 15 in the X-axis direction is referred to as “width” for the sake of convenience.

As illustrated in FIGS. 2 to 5, the wiring member 15 includes a body portion 50, and ridges 60 (61, 62, 63, and 64). The body portion 50 is a band-shaped portion elongated in the Y-axis direction. Specifically, the body portion 50 extends in the Y-axis direction over the semiconductor chip 30 and the conductive patterns 23. As illustrated in FIGS. 2 and 3, the body portion 50 of the first embodiment includes a first end portion 51, a second end portion 52, an extending portion 53, a first coupling portion 54, and a second coupling portion 55.

The first end portion 51 is an end portion of the body portion 50 in the Y1 direction. The second end portion 52 is an end portion of the body portion 50 on the opposite side (that is, in the Y2 direction) of the body portion 50 to the first end portion 51. The first end portion 51 and the second end portion 52 are flat plate-shaped portions parallel to an X-Y plane. The first end portion 51 is joined to the semiconductor chip 30 and the second end portion 52 is joined to the conductive pattern 23b. Specifically, as illustrated in FIG. 1, the first end portion 51 is joined to the second main electrode 32 of the semiconductor chip 30 by a joining material C3, and the second end portion 52 is joined to the conductive pattern 23b by a joining material C4. The joining materials C3 and C4 are, for example, conductive materials such as solder or a sintered material. As described above, the first end portion 51 is electrically connected to the semiconductor chip 30.

The extending portion 53 in FIG. 2 is a portion linearly extending in the Y-axis direction between the first end portion 51 and the second end portion 52. The extending portion 53 is a flat plate-shaped portion parallel to the X-Y plane. The first end portion 51 is positioned in the Y1 direction of the extending portion 53 in plan view and the second end portion 52 is positioned in the Y2 direction of the extending portion 53 in plan view.

A width B1 of the first end portion 51 is greater than a width Bc of the extending portion 53 (B1>Bc). Similarly, a width B2 of the second end portion 52 is greater than the width Bc of the extending portion 53 (B2>Bc). The width Bc of the extending portion 53 may be the same as the width B1 of the first end portion 51 or the width B2 of the second end portion 52. The width B1 of the first end portion 51 and the width B2 of the second end portion 52 are equal to each other. In some embodiments, the width B1 of first end portion 51 and the width B2 of the second end portion 52 may be different from each other.

The extending portion 53 is positioned in the Z2 direction relative to the first end portion 51 on the Z-axis. That is, the position of the extending portion 53 on the Z-axis is in the Z2 direction relative to the position of the first end portion 51 on the Z-axis. The first coupling portion 54 is a riser portion bent to couple the first end portion 51 to the extending portion 53. Of the first coupling portion 54, the width of a portion adjacent to the first end portion 51 is substantially the same as the width B1 of the first end portion 51, and the width of a portion adjacent to the extending portion 53 is substantially the same as the width Bc of the extending portion 53.

The extending portion 53 is positioned in the Z2 direction relative to the second end portion 52 on the Z-axis. That is, the position of the extending portion 53 on the Z-axis is in the Z2 direction relative to the position of the second end portion 52 on the Z-axis. The second coupling portion 55 is a riser portion bent to couple the second end portion 52 to the extending portion 53. Of the second coupling portion 55, the width of a portion adjacent to the second end portion 52 is substantially the same as the width B2 of the second end portion 52, and the width of a portion adjacent to the extending portion 53 is substantially the same as the width Bc of the extending portion 53.

Each of the ridges 60 of the wiring member 15 is a structure for reinforcing the wiring member 15. A ridge 60 extends along the longitudinal direction (that is, the Y-axis direction) of the wiring member 15. The ridge 60 protrudes from the surface of a flat plate-shaped portion (specifically, the extending portion 53 and the first end portion 51) of the body portion 50. The ridges 60 include a first ridge 61, a second ridge 62, a third ridge 63, and a fourth ridge 64. The first ridge 61 and the second ridge 62 are provided on the extending portion 53. The third ridge 63 and the fourth ridge 64 are provided on the first end portion 51.

FIG. 4 is a cross-sectional view of the extending portion 53. As illustrated in FIGS. 3 and 4, the extending portion 53 is a flat plate-shaped portion including a first face F1 and a second face F2. The first face F1 and the second face F2 are flat surfaces parallel to the X-Y plane. The first face F1 is a principal surface positioned in the Z1 direction in the extending portion 53. The second face F2 is a principal surface on the opposite side of the extending portion 53 to the first face F1. In other words, the first face F1 is a principal surface adjacent to the mounting board 20. The first ridge 61 and the second ridge 62 protrude in the Z1 direction from the first face F1.

As illustrated in FIGS. 2 and 4, the extending portion 53 includes a first edge E1 and a second edge E2. The first edge E1 and the second edge E2 are edges extending along the Y-axis. The first edge E1 and the second edge E2 are positioned on opposite sides to each other in the X-axis direction (that is, the width direction). In other words, the first edge E1 is an edge positioned in the X1 direction in the extending portion 53 and the second edge E2 is an edge positioned in the X2 direction in the extending portion 53.

The first ridge 61 extends in the Y-axis direction along the first edge E1. Specifically, the first ridge 61 protrudes in the Z1 direction from the first edge E1 of the first face F1 of the extending portion 53. The second ridge 62 extends in the Y-axis direction along the second edge E2. Specifically, the second ridge 62 protrudes in the Z1 direction from the second edge E2 of the first face F1 of the extending portion 53. As will be understood from the above explanations, the first ridge 61 and the second ridge 62 extend in parallel to each other with a certain space therebetween in the X-axis direction. The first ridge 61 and the second ridge 62 extend over substantially the entire length of the extending portion 53 in the Y-axis direction. However, the first ridge 61 and the second ridge 62 may be arranged in a certain range of the extending portion 53 in the Y-axis direction.

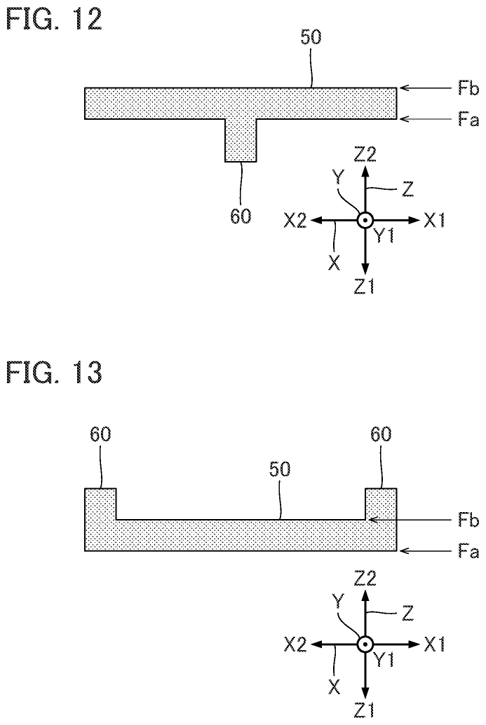

As described above, since the first ridge 61 and the second ridge 62 are formed on the extending portion 53 of the wiring member 15 in the first embodiment, second moment of area (and also stiffness) of the extending portion 53 is greater than in a mode in which the first ridge 61 and the second ridge 62 are not formed. Therefore, according to the first embodiment, deformation of the extending portion 53, for example, in the course of transportation or assembly can be minimized. Particularly in the first embodiment, the first ridge 61 and the second ridge 62 are arranged spaced apart from each other in the width direction of the extending portion 53. Accordingly, deformation of the extending portion 53 can be more effectively minimized than in a mode (for example, FIG. 12 described later) in which only one ridge 60 is arranged on the extending portion 53.

As illustrated in FIG. 4, a height Ha of the first ridge 61 and a height Ha of the second ridge 62 are equal to each other. The height Ha is a distance between the first face F1 of the extending portion 53 and the top face of the first ridge 61 or the second ridge 62. As illustrated in FIG. 4, the heights Ha of the first ridge 61 and the second ridge 62 are equal to or greater than a plate thickness Ta of the extending portion 53 (Ha≥Ta). The plate thickness Ta of the extending portion 53 is the distance between the first face F1 and the second face F2. A configuration in which the heights Ha of the first ridge 61 and the second ridge 62 are less than the plate thickness Ta of the extending portion 53 is also conceivable.

The plate thickness Ta is, for example, a dimension not less than 0.1 mm (millimeter) and not greater than 2.0 mm. Specifically, the plate thickness Ta is, for example, a dimension not less than 0.2 mm and not greater than 1.0 mm. More specifically, the plate thickness Ta is set to be, for example, equal to or less than 0.5 mm. Particularly in a mode in which the plate thickness Ta is equal to or less than 0.5 mm, the insufficient strength of the wiring member 15 may become apparent. Therefore, the first embodiment that can minimize deformation of the wiring member 15 (the extending portion 53) by way of the ridges 60 is particularly effective.

As illustrated in FIG. 4, a width Wa of the first ridge 61 and a width Wa of the second ridge 62 are equal to each other. The width Wa is a dimension of the first ridge 61 or the second ridge 62 in the X-axis direction and is set to be, for example, equal to or greater than 0.1 mm. As illustrated in FIG. 4, the heights Ha of the first ridge 61 and the second ridge 62 are equal to or greater than the widths Wa of the first ridge 61 and the second ridge 62 (Ha≥Wa).

FIG. 5 is a cross-sectional view of the first end portion 51. As illustrated in FIGS. 3 and 5, the first end portion 51 is a flat plate-shaped portion including a third face F3 and a fourth face F4. The third face F3 and the fourth face F4 are flat surfaces parallel to the X-Y plane. The third face F3 is a principal surface positioned in the Z1 direction in the first end portion 51. The fourth face F4 is a principal surface on the opposite side of the first end portion to the third face F3. In other words, the third face F3 is a principal surface adjacent to the mounting board 20. The third ridge 63 and the fourth ridge 64 protrude in the Z1 direction from the third face F3.

As illustrated in FIGS. 2 and 5, the first end portion 51 includes a third edge E3 and a fourth edge E4. The third edge E3 and the fourth edge E4 are edges extending along the Y-axis. The third edge E3 and the fourth edge E4 are positioned on opposite sides to each other in the X-axis direction (that is, the width direction). That is, the third edge E3 is an edge positioned in the X1 direction in the first end portion 51 and the fourth edge E4 is an edge positioned in the X2 direction in the first end portion 51.

The third ridge 63 extends in the Y-axis direction along the third edge E3. Specifically, the third ridge 63 protrudes in the Z1 direction from the third edge E3 of the third face F3 of the first end portion 51. The fourth ridge 64 extends in the Y-axis direction along the fourth edge E4. Specifically, the fourth ridge 64 protrudes in the Z1 direction from the fourth edge E4 of the third face F3 of the first end portion 51. As will be understood from the above explanations, the third ridge 63 and the fourth ridge 64 extend in parallel to each other with a certain space therebetween in the X-axis direction.

As described above, the first end portion 51 is joined to the semiconductor chip 30 by way of the joining material C3. Specifically, the third face F3 of the first end portion 51 and the second main electrode 32 of the semiconductor chip 30 are joined to each other. As illustrated in FIG. 5, the joining material C3 is filled in the space between the third ridge 63 and the fourth ridge 64.

As described above, since the third ridge 63 and the fourth ridge 64 are formed on the first end portion 51 of the wiring member 15 in the first embodiment, second moment of area (and also stiffness) of the first end portion 51 is greater than in a mode in which the third ridge 63 and the fourth ridge 64 are not formed. Therefore, according to the first embodiment, deformation of the first end portion 51, for example, in the course of transportation or assembly can be minimized. Particularly in the first embodiment, the third ridge 63 and the fourth ridge 64 are arranged spaced apart from each other in the width direction of the first end portion 51. Accordingly, deformation of the first end portion 51 can be more effectively minimized as compared to a mode in which only one ridge 60 is arranged on the first end portion 51.

As illustrated in FIG. 5, a height Hb of the third ridge 63 and a height Hb of the fourth ridge 64 are equal to each other. The heights Hb of the third ridge 63 and the fourth ridge 64 are equal to or less than a plate thickness Tb of the first end portion 51 (Hb≤Tb). The body portion 50 of the first embodiment has a uniform plate thickness throughout. Accordingly, the plate thickness Tb of the first end portion 51 and the plate thickness Ta of the extending portion 53 are equal to each other.

The height Ha of the first ridge 61 and the height Hb of the third ridge 63 may be equal to or different from each other. For example, the height Ha of the first ridge 61 and the height Hb of the third ridge 63 may be equal to each other. The height Ha of the first ridge 61 may be greater than the height Hb of the third ridge 63. The height Ha of the first ridge 61 may be less than the height Hb of the third ridge 63.

The width Wb of the third ridge 63 and the width Wb of the fourth ridge 64 are equal to each other. The width Wb is a dimension of the third ridge 63 or the fourth ridge 64 in the X-axis direction and is set to be, for example, equal to or greater than 0.1 mm. As illustrated in FIG. 5, the heights Hb of the third ridge 63 and the fourth ridge 64 are equal to or greater than the widths Wb of the third ridge 63 and the fourth ridge 64 (Hb≥Wb).

The width Wa of the first ridge 61 and the width Wb of the third ridge 63 may be equal to or different from each other. For example, a mode in which the width Wa of the first ridge 61 and the width Wb of the third ridge 63 are equal to each other is conceivable. The width Wa of the first ridge 61 may be greater than the width Wb of the third ridge 63. The width Wa of the first ridge 61 may be less than the width Wb of the third ridge 63.

As described above, the heights H (Ha and Hb) of the ridges 60 are equal to or greater than the widths W (Wa and Wb) of the ridges 60 in the first embodiment.

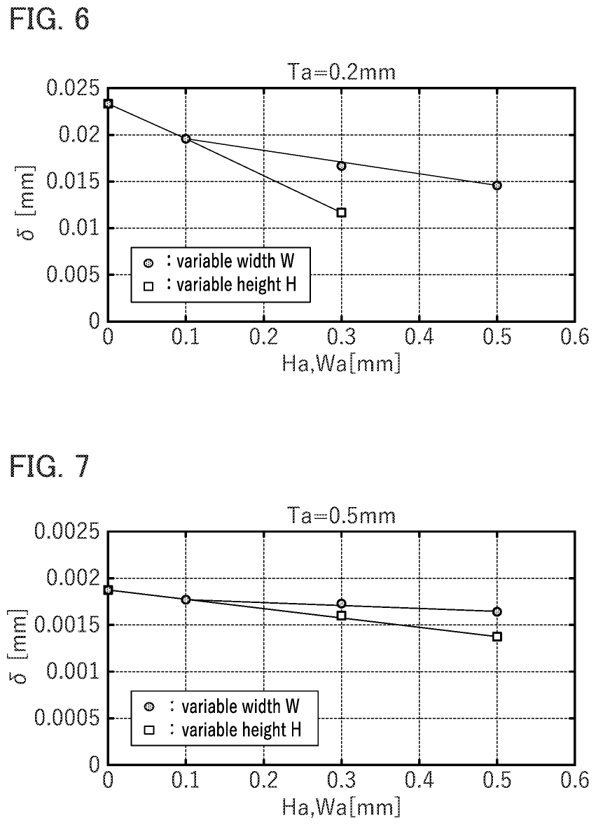

FIGS. 6 and 7 are graphs indicating relationships between (i) the heights H and the widths W (the horizontal axis) of the ridges 60 and (ii) the maximum deformation amount δ (the vertical axis) of the wiring member 15. The horizontal axes in FIGS. 6 and 7 correspond to the heights Ha and the widths Wa of the first ridge 61 and the second ridge 62, and the vertical axes correspond to the maximum value of the deformation amount of the extending portion 53 of the wiring member 15. FIG. 6 is a graph in a case in which the plate thickness Ta of the body portion 50 of the wiring member 15 is set to 0.2 mm, and FIG. 7 is a graph in a case in which the plate thickness Ta of the body portion 50 is set to 0.5 mm. Each graph shows a case in which the width Wa is changed and a case in which the height Ha is changed. In the case in which the width Wa is changed, the height Ha is 0.1 mm when the width Wa≥0.1 mm is satisfied. In the case in which the height Ha is changed, the width Wa is 0.1 mm when the height Ha≥0.1 mm is satisfied.

As may be seen in FIGS. 6 and 7, effects of the heights H of the ridges 60 on the maximum deformation amount δ are greater than those of the widths W of the ridges 60. That is, when the height H of a ridge 60 is increased, the stiffness of the wiring member 15 is increased more than in a case in which the width W of the ridge 60 is increased. Considering this tendency, the heights H of the ridges 60 are equal to or greater than the widths W thereof in the first embodiment. As will be understood from FIGS. 6 and 7, the configuration described above can more efficiently improve the stiffness of the wiring member 15 as compared to a mode in which the heights H of the ridges 60 are less than the widths W thereof.

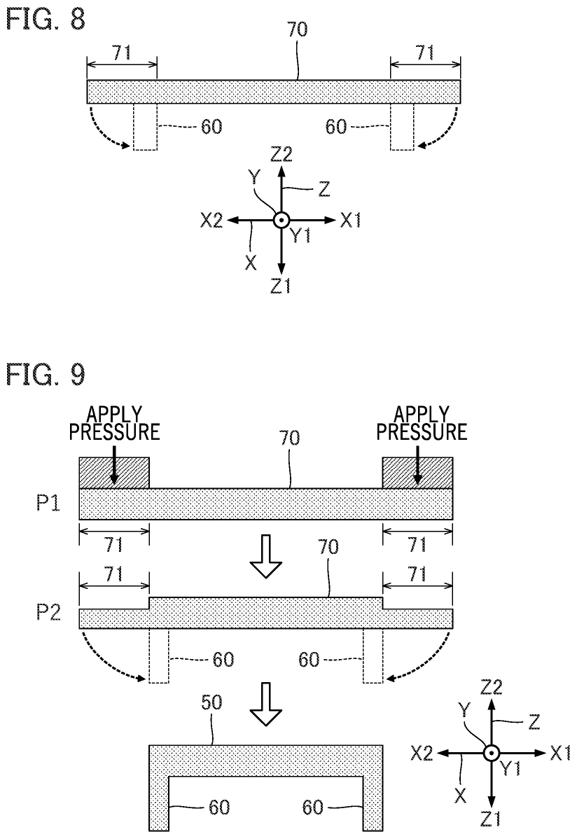

FIG. 8 is an explanatory diagram of a manufacturing method of the wiring member 15 according to the first embodiment. As illustrated in FIG. 8, the wiring member 15 of the first embodiment is manufactured by stamping (specifically, bending work) of a metal plate-shaped member 70. Specifically, portions (hereinafter, “edge end portions 71”) near both edges of the plate-shaped member 70 are bent by applying pressure to form the ridges 60. For example, in a process of bending the body portion 50, the ridges 60 are also formed at the same time. However, bending of the body portion 50 and formation of the ridges 60 may be performed in different processes. In the wiring member 15 manufactured by the manufacturing method illustrated in FIG. 8, the widths W (Wa and Wb) of the ridges 60 are equal to the plate thicknesses T (Ta and Tb) of the body portion 50 (W=T). The heights Ha of the ridges 60 are freely selected according to the widths of the edge end portions 71.

### B: Second Embodiment

FIG. 9 is an explanatory diagram of a manufacturing method of the wiring member 15 according to a second embodiment. As illustrated in FIG. 9, the wiring member 15 of the second embodiment is manufactured by a first process P1 and a second process P2.

In the first process P1, stamping of a metal plate-shaped member 70 is performed. Specifically, the edge end portions 71 of the plate-shaped member 70 have pressure applied to make the edge end portions 71 thinner so that the edge end portions 71 are thinner than a portion except for the edge end portions 71.

In the second process P2 after the first process P1 is performed, the edge end portions 71 are bent by applying pressure to form the ridges 60. In the wiring member 15 manufactured by the manufacturing method illustrated in FIG. 9, the widths W (Wa and Wb) of the ridges 60 are smaller than the plate thicknesses T (Ta and Tb) of the body portion 50 (W<T).

### C: Third Embodiment

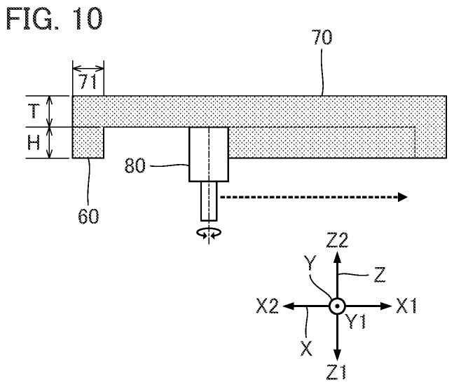

FIG. 10 is an explanatory diagram of a manufacturing method of the wiring member 15 according to a third embodiment. In the third embodiment, as illustrated in FIG. 10, the wiring member 15 is manufactured by cutting work of a metal plate-shaped member 70. A rotary cutting tool (an end mill) 80 is used in the cutting work. The cutting tool 80 is movable to any position in the X-Y plane while rotating.

The plate thickness of the plate-shaped member 70 is set to the sum of the plate thickness T of the body portion 50 and the height H of each of the ridges 60. As illustrated in FIG. 10, a region of the plate-shaped member 70 other than the edge end portions 71 is cut (end-milled) by the cutting tool 80 partly in the plate thickness direction. Portions (the edge end portions 71) of the plate-shaped member 70 that have not been cut (end-milled) correspond to the ridges 60. That is, the depth of the cutting corresponds to the height H of each of the ridges 60. According to the manufacturing method illustrated in FIG. 10, the heights H and the widths W of the ridges 60 can be freely set.

### D: Modifications

Specific modifications added to each of the embodiments exemplified above are exemplified below. Two or more modes freely selected from the following exemplifications may be appropriately combined with each other as long as they do not conflict. In the following explanations, a surface facing the Z1 direction of the body portion 50 of the wiring member 15 is referred to as a “lower surface Fa” and a surface facing the Z2 direction of the body portion 50 is referred to as an “upper surface Fb”. The first face F1 and the third face F3 described above are included in the lower surface Fa, and the second face F2 and the fourth face F4 are included in the upper surface Fb.

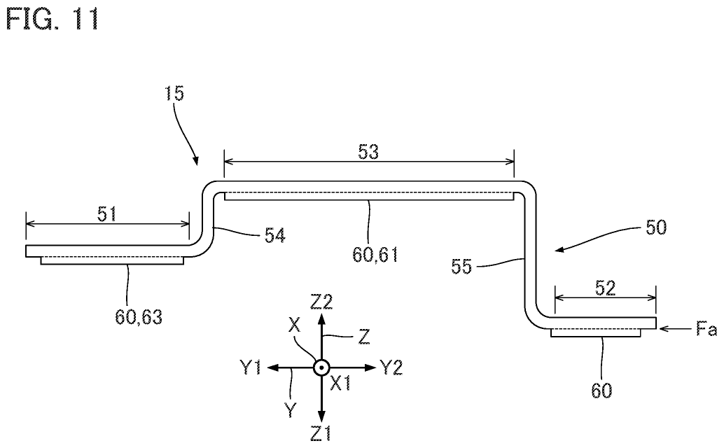

(1) The ridges 60 are formed on the extending portion 53 and the first end portion 51 of the body portion 50 in the above embodiments. However, the positions at which the ridges 60 are formed on the body portion 50 can be freely selected. For example, one or more ridges 60 may be arranged also on the second end portion 52 in addition to the extending portion 53 and the first end portion 51. For example, as illustrated in FIG. 11, two ridges 60 may be arranged on the lower surface Fa of the second end portion 52.

In a configuration in which the ridges 60 (the first ridge 61 and the second ridge 62) are arranged on the extending portion 53, the ridges 60 (the third ridge 63 and the fourth ridge 64) on the first end portion 51 may be omitted. A mode in which the ridges 60 are formed on one or both of the first end portion 51 and the second end portion 52, and no ridge 60 is formed on the extending portion 53, is also conceivable. However, since the extending portion 53 has the greatest dimension in the Y-axis direction in the body portion 50, the extending portion 53 is more likely to deform than the first end portion 51 or the second end portion 52. Therefore, a configuration in which the ridges 60 are arranged on the extending portion 53 is favorable in view of minimizing deformation of the wiring member 15.

(2) The number of the ridges 60 on the wiring member 15 is not limited to the examples described in the above embodiments. For example, one ridge 60 may be arranged at the center of the body portion 50 (for example, the extending portion 53, the first end portion 51, or the second end portion 52) in the X-axis direction as illustrated in FIG. 12. In the configuration illustrated in FIG. 12, one ridge 60 is arranged on the lower surface Fa of the body portion 50. The ridge 60 extends linearly along the Y-axis.

(3) The positions where the ridges 60 are arranged on the body portion 50 are not limited to the examples described in the above embodiments. For example, although the ridges 60 are arranged on the lower surface Fa (the first face F1 and the third face F3) of the body portion 50 in the above embodiments, one or more ridges 60 may be arranged on the upper surface Fb (the second face F2 and the fourth face F4) of the body portion 50 as illustrated in FIG. 13. The ridges 60 in FIG. 13 extend in the Y-axis direction along the edges of the body portion 50 and protrude in the Z2 direction from the upper surface Fb of the body portion 50. One ridge 60 may be arranged on the upper surface Fb of the body portion 50.

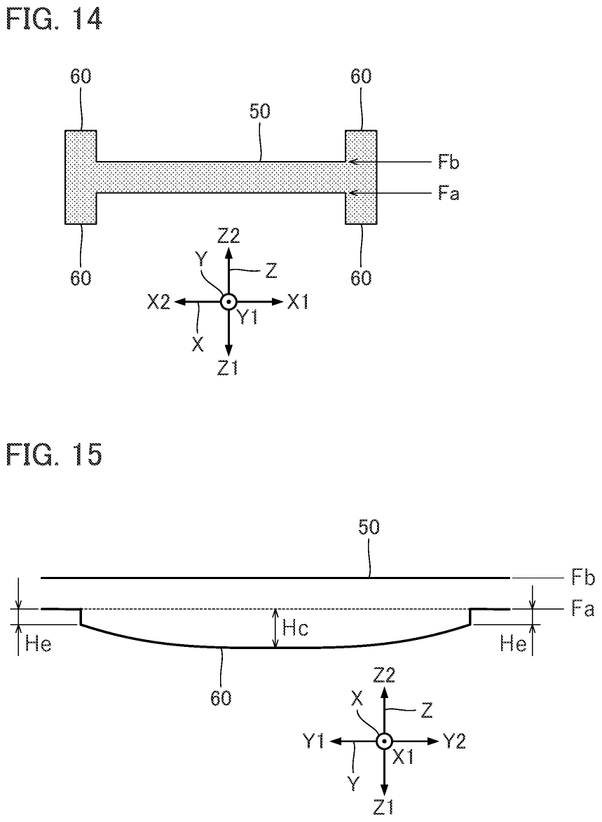

With the ridges 60 arranged on the upper surface Fb of the body portion 50, the liquid sealing material 13 can be more easily supplied immediately under the body portion 50 in the process of filling the sealing material 13 in a space inside the housing 11 compared with the mode in which the ridges 60 are arranged on the lower surface Fa (for example, the first embodiment). On the other hand, according to the mode in which the ridges 60 are arranged on the lower surface Fa of the body portion 50, the dimension (that is, the height) of the wiring member 15 in the Z direction can be minimized as compared to the mode in which the ridges 60 are arranged on the upper surface Fb (for example, FIG. 13). As illustrated in FIG. 14, one or more ridges 60 may be arranged on both the lower surface Fa and the upper surface Fb of the body portion 50.

The modes described in the embodiments and the modifications described above (FIGS. 11 to 14) are comprehensively expressed as a configuration in which one or more ridges 60 extending in the Y-axis direction are arranged on the body portion 50 of the wiring member 15. According to this configuration, second moment of area (stiffness) of the body portion 50 is improved as compared to a mode in which no ridge 60 is arranged on the body portion 50. Therefore, as described also in the first embodiment, deformation of the wiring member 15 (the body portion 50), for example, in the course of transportation or assembly can be minimized.

(4) The height H of each of the ridges 60 is constant over the entire length in the Y-axis direction in the above embodiments. However, the height H of each of the ridges 60 may vary. For example, the height H of each of the ridges 60 may differ according to the positions on the Y-axis, as illustrated in FIG. 15. In the mode illustrated in FIG. 15, the height H of each of the ridges 60 changes continuously according to the positions on the Y-axis in such a manner that a height Hc at the central portion of the ridge 60 in the Y-axis direction is greater than heights He at both end portions of the ridge 60. The height H of each of the ridges 60 may change stepwise according to the positions on the Y-axis.

(5) The width W of each of the ridges 60 is constant over the entire length in the Y-axis direction in the above embodiments. However, the width W of each of the ridges 60 may vary. For example, the width W of each of the ridges 60 may differ according to the positions on the Y-axis. For example, the width W of each of the ridges 60 may change continuously or stepwise according to the positions on the Y-axis in such a manner that the width at the central portion of the ridge 60 in the Y-axis direction is greater than the widths at both end portions of the ridge 60.

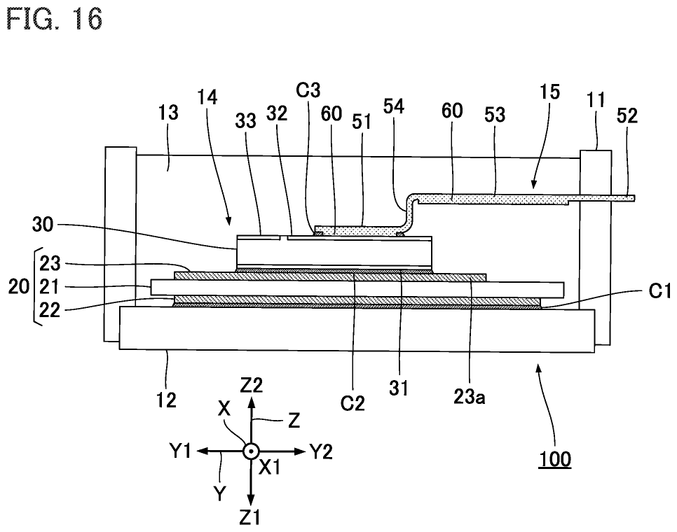

(6) Both the first end portion 51 and the second end portion 52 of the wiring member 15 are positioned inside the housing 11 in the above embodiments. However, the second end portion 52 may be positioned outside the housing 11, as illustrated in FIG. 16. The second end portion 52 in FIG. 16 is used as an external terminal for electrically connecting the semiconductor unit 14 to an external device. As will be understood from the above illustrations, the configuration in which both end portions of the wiring member 15 are joined to the semiconductor unit 14, and the configuration in which the entire wiring member 15 is positioned inside the housing 11, are not essential.

(7) Although an IGBT is exemplified as the semiconductor chip 30, the mode of the semiconductor chip 30 is not limited to the above example. For example, a MOSFET (Metal Oxide Semiconductor Field Effect Transistor), an FWD (Freewheeling Diode), an RC-IGBT (Reverse Conducting IGBT), or an SBD (Schottky Barrier Diode) may be used as the semiconductor chip 30. A MOSFET semiconductor layer is made of, for example, silicon (Si) or silicon carbide (SiC). In a mode in which a MOSFET is adopted as the semiconductor chip 30, the first main electrode 31 is a drain electrode and the second main electrode 32 is a source electrode.

(8) The descriptions “nth” (n is a natural number) in the present application are merely used as formal and expedient indicators (labels) for distinguishing elements in the descriptions, and they do not have any substantive meanings. Therefore, the descriptions “nth” do not limit the interpretation of the positions of elements, the order of manufacturing thereof, or the like.

### E: Appendices

For example, the following configurations are derivable from the modes exemplified above.

A semiconductor module according to one aspect (Aspect 1) of the present disclosure includes: a semiconductor chip arranged on a substrate; and a wiring member electrically connected to the semiconductor chip, in which the wiring member includes: a body portion elongated in a first direction; and one or more ridges protruding from a surface of a flat plate-shaped portion of the body portion and extending along the first direction. In this aspect, stiffness of the wiring member is improved by the configuration in which one or more ridges along the first direction protrude from a surface of the extending portion as compared to a configuration in which no ridges are arranged. Therefore, deformation of the wiring member, for example, in the course of transportation or assembly, can be minimized.

In a specific example (Aspect 2) of Aspect 1, the body portion includes: a first end portion joined to the semiconductor chip; a second end portion on an opposite side of the first end portion; and an extending portion extending in the first direction between the first end portion and the second end portion, and the one or more ridges include a first ridge arranged on the extending portion. In this aspect, the first ridge is formed on the extending portion extending in the first direction in the body portion. Therefore, deformation of the extending portion can be minimized.

In a specific example (Aspect 3) of Aspect 2, the one or more ridges include a second ridge arranged on the extending portion, and the extending portion includes: a first edge along the first direction; and a second edge along the first direction on an opposite side of the first edge in a width direction of the extending portion, the first ridge extends along the first edge, and the second ridge extends along the second edge. In this aspect, the first ridge along the first edge of the extending portion and the second ridge along the second edge of the extending portion are arranged. That is, the first ridge and the second ridge are arranged spaced apart from each other in the width direction of the extending portion. Therefore, deformation of the extending portion can be more effectively minimized as compared to a mode in which only the first ridge is arranged on the extending portion.

In a specific example (Aspect 4) of Aspect 3, the extending portion includes: a first face adjacent to the substrate; and a second face opposite to the first face, and the first ridge and the second ridge protrude from the first face. In this aspect, the first ridge and the second ridge protrude from the first face of the extending portion. Therefore, the height of the wiring member can be reduced as compared to, for example, a mode in which the first ridge and the second ridge protrude from the second face of the extending portion.

In a specific example (Aspect 5) of any one of Aspects 2 to 4, the one or more ridges include a third ridge arranged on the first end portion. In this aspect, the third ridge is formed on the first end portion joined to the semiconductor chip in the body portion. Therefore, deformation of the first end portion can be minimized.

In a specific example (Aspect 6) of Aspect 5, the one or more ridges include a fourth ridge arranged on the first end portion, the first end portion includes: a third edge along the first direction; and a fourth edge along the first direction on an opposite side of the third edge in a width direction of the first end portion, the third ridge extends along the third edge, and the fourth ridge extends along the fourth edge. In this aspect, the third ridge along the third edge of the first end portion and the fourth ridge along the fourth edge of the first end portion are arranged. That is, the third ridge and the fourth ridge are arranged spaced apart from each other in the width direction of the first end portion. Therefore, deformation of the first end portion can be more effectively minimized as compared to a mode in which only the third ridge is arranged on the first end portion.

In a specific example (Aspect 7) of Aspect 6, the first end portion includes: a third face joined to the semiconductor chip; and a fourth face opposite to the third face, and the third ridge and the fourth ridge protrude from the third face. In this aspect, the third ridge and the fourth ridge protrude from the third face of the first end portion. Therefore, the height of the wiring member can be reduced, for example, as compared to a mode in which the third ridge and the fourth ridge protrude from the fourth face of the first end portion.

In a specific example (Aspect 8) of any one of Aspects 1 to 7, heights of the one or more ridges are equal to or greater than widths of the one or more ridges. Effects of the heights of the ridges on the deformation amount of the wiring member are greater than those of the widths of the ridges. Therefore, according to the configuration in which the heights of the ridges are equal to or greater than the widths thereof, stiffness of the wiring member can be more efficiently improved as compared to a mode in which the heights of the ridges are less than the widths thereof.

A wiring member according to one aspect (Aspect 9) of the present disclosure is a wiring member electrically connected to a semiconductor chip, and includes: a body portion elongated in a first direction; and one or more ridges protruding from a surface of a flat plate-shaped portion of the body portion and extending along the first direction.

### DESCRIPTION OF REFERENCE SIGNS

100 . . . semiconductor module, 11 . . . housing, 12 . . . heatsink, 13 . . . sealing material, 14 . . . semiconductor unit, 15 . . . wiring member, 20 . . . mounting board, 21 . . . insulating substrate, 22 . . . metal layer, 23 (23a, 23b) . . . conductive pattern, 30 . . . semiconductor chip, 31 . . . first main electrode, 32 . . . second main electrode, 33 . . . control electrode, 50 . . . body portion, 51 . . . first end portion, 52 . . . second end portion, 53 . . . extending portion, 54 . . . first coupling portion, 55 . . . second coupling portion, 60 . . . ridge, 61 . . . first ridge, 62 . . . second ridge, 63 . . . third ridge, 64 . . . fourth ridge.

What is claimed is:

1. A semiconductor module comprising:
a semiconductor chip arranged on a substrate; and
a wiring member electrically connected to the semiconductor chip,
wherein the wiring member includes:
a body portion elongated in a first direction; and
one or more ridges protruding from a surface of a flat plate-shaped portion of the body portion and extending along the first direction.

2. The semiconductor module according to claim 1, wherein:
the body portion includes:
a first end portion joined to the semiconductor chip;
a second end portion on an opposite side of the first end portion; and
an extending portion extending in the first direction between the first end portion and the second end portion, and
the one or more ridges include a first ridge arranged on the extending portion.

3. The semiconductor module according to claim 2, wherein:
the one or more ridges include a second ridge arranged on the extending portion, and
the extending portion includes:
a first edge along the first direction; and
a second edge along the first direction on an opposite side of the first edge in a width direction of the extending portion,
the first ridge extends along the first edge, and
the second ridge extends along the second edge.

4. The semiconductor module according to claim 3, wherein:
the extending portion includes:
a first face adjacent to the substrate; and
a second face opposite to the first face, and
the first ridge and the second ridge protrude from the first face.

5. The semiconductor module according to claim 2, wherein the one or more ridges include a third ridge arranged on the first end portion.

6. The semiconductor module according to claim 5, wherein:
the one or more ridges include a fourth ridge arranged on the first end portion,
the first end portion includes:
a third edge along the first direction; and
a fourth edge along the first direction on an opposite side of the third edge in a width direction of the first end portion,
the third ridge extends along the third edge, and
the fourth ridge extends along the fourth edge.

7. The semiconductor module according to claim 6, wherein:
the first end portion includes:
a third face joined to the semiconductor chip; and
a fourth face opposite to the third face, and
the third ridge and the fourth ridge protrude from the third face.

8. The semiconductor module according to claim 1, wherein heights of the one or more ridges are equal to or greater than widths of the one or more ridges.

9. A wiring member electrically connected to a semiconductor chip, the wiring member comprising:
a body portion elongated in a first direction; and
one or more ridges protruding from a surface of a flat plate-shaped portion of the body portion and extending along the first direction.
